(19) United States
(12) Patent Application Publication
(10) Pub. No.: US 2008/0165514 A1
(43) Pub. Date: Jul. 10, 2008

(54) PRINTED CIRCUIT BOARD

(75) Inventor: Yong-won HWANG, Hwaseong-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/762,365

(22) Filed: Jun. 13, 2007

(30) Foreign Application Priority Data
Jan. 5, 2007 (KR) 2007-1711

(51) Int. Cl. H05K 3/00; H05K 7/02

(52) U.S. Cl. 361/780; 29/832

(57) ABSTRACT

A printed circuit board (PCB) having a multi-layered structure for improving shielding against electromagnetic interference, the PCB including one or more signal layers and an outer grounding layer located on an outermost surface of the PCB. Accordingly, the radiation of electromagnetic waves to the outside from the outer grounding layer is prevented.

### CROSS-REFERENCE TO RELATED APPLICATIONS

This application claims all benefits accruing under 35 U.S.C. §119 from Korean Patent Application No. 2007-1711, filed on Jan. 5, 2007 in the Korean Intellectual Property Office, the disclosure of which is incorporated herein by reference.

### BACKGROUND OF THE INVENTION

1. Field of the Invention

Aspects of the present invention relate to a printed circuit board (PCB), and more particularly, to a PCB having a multi-layered structure in which electromagnetic interference (EMI) shielding is improved.

2. Related Art

Generally, a printed circuit board (PCB) includes a signal layer, a power layer, and a grounding layer, in which electronic parts are included. The signal layer, the power layer, and the grounding layer are insulated from each other using a dielectric material. The signal layer provides a pathway for electric signals inputted to and outputted from electronic parts, and forms a wire circuit for the electronic parts.

However, lines formed between the signal layer, the power layer, and the grounding layer of the PCB become antennas. Thus, these electrical lines can radiate electromagnetic waves that can cause a malfunction of electronic devices. Therefore, the shielding against electromagnetic interference (EMI) caused by the electromagnetic waves is an important consideration in manufacturing the PCBs.

### SUMMARY OF THE INVENTION

Aspects of the present invention provide a printed circuit board having an improved structure for shielding against electromagnetic interference (EMI).

Additional aspects and/or advantages of the invention will be set forth in part in the description which follows and, in part, will be obvious from the description, or may be learned by practice of the invention.

According to an aspect of the present invention, there is provided a printed circuit board (PCB) having a multi-layered structure to connect to electronic parts and to shield against electromagnetic interference caused by radiation of electromagnetic waves. Such a PCB comprises: one or more signal layers to provide lines for electrical signals inputted to and outputted from the electronic parts, and an outer grounding layer located on an outermost surface of the PCB to block radiation of electromagnetic waves radiated from the lines of the one or more signal layers.

The one or more signal layers may include a first signal layer located on another outermost surface opposite to the outermost surface where the outer grounding layer is located, and the PCB may further include a power layer between the first signal layer and the outer grounding layer to supply power to the electronic parts.

The one or more signal layers may further include a second signal layer located between the outer grounding layer and the first signal layer.

The printed circuit board may further include a power layer between the first signal layer and the second signal layer to supply power to the electronic parts.

The printed circuit board may further include an intermediate grounding layer between the first signal layer and the second signal layer to block radiation of electromagnetic waves radiated from the lines of the one or more signal layers.

The printed circuit board may further include a power layer and an intermediate grounding layer, which are provided in the same layer in different regions, between the first signal layer and the second signal layer.

Electronic parts having relatively low speed clock signals may be connected to the outer grounding layer, and electronic parts having relatively high speed clock signals may be connected to the intermediate grounding layer.

Electronic parts having relatively low speed clock signals may be connected to the first signal layer, and electronic parts having relatively high speed clock signals may be connected to the second signal layer.

According to another aspect of the present invention, there is provided a method of shielding against electromagnetic interference from a printed circuit board caused by radiation of electromagnetic waves. Such a method comprises: inputting and/or outputting electrical signals to/from electronic parts in one or more signal layers of the printed circuit board; and blocking radiation of electromagnetic waves radiated from the one or more signal layers with an outer grounding layer located on an outermost surface of the printed circuit board.

According to still another aspect of the present invention, there is provided a printed circuit board having a multi-layered structure to connect to electronic parts and to shield against electromagnetic interference caused by radiation of electromagnetic waves. Such a printed circuit board comprises: one or more signal layers to provide lines for electrical signals inputted to and outputted from the electronic parts; an intermediate grounding layer located within the printed circuit board to block radiation of electromagnetic waves radiated from the lines of the one or more signal layers; and an outer grounding layer located on an outermost surface of the printed circuit board to block the radiation of the electromagnetic waves radiated from the lines of the one or more signal layers.

In addition to the example embodiments and aspects as described above, further aspects and embodiments will be apparent by reference to the drawings and by study of the following descriptions.

### BRIEF DESCRIPTION OF THE DRAWINGS

A better understanding of the present invention will become apparent from the following detailed description of example embodiments and the claims when read in connection with the accompanying drawings, all forming a part of the disclosure of this invention. While the following written and illustrated disclosure focuses on disclosing example embodiments of the invention, it should be clearly understood that the same is by way of illustration and example only and that the invention is not limited thereto. The spirit and scope of the present invention are limited only by the terms of the appended claims. The following represents brief descriptions of the drawings, wherein:

FIG. 1 is a cross-sectional view illustrating a printed circuit board (PCB) according to an example embodiment of the present invention;

FIG. 2 is a schematic cross-sectional view illustrating the shielding against electromagnetic interference (EMI) of the PCB according to an example embodiment of the present invention;

FIG. 3 is a schematic cross-sectional view illustrating a PCB according to another example embodiment of the present invention;

FIG. 4 is a schematic cross-sectional view illustrating a PCB according to another example embodiment of the present invention; and

FIG. 5 is a schematic cross-sectional view illustrating a PCB according to yet another example embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

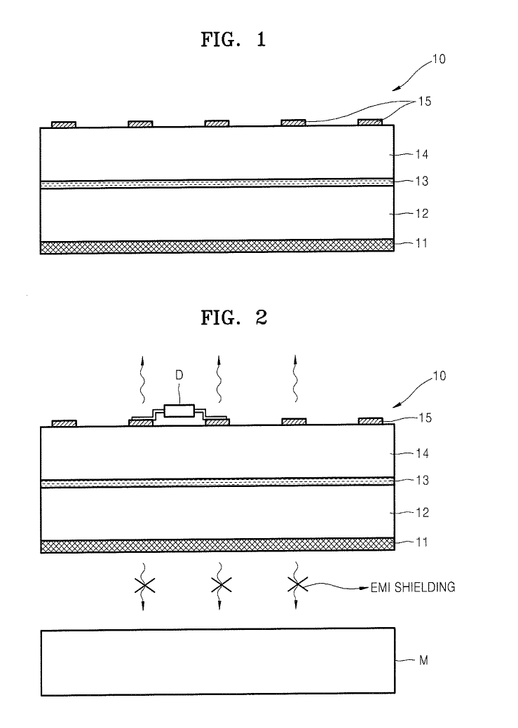

FIG. 1 is a cross-sectional view illustrating a PCB 10 according to an example embodiment of the present invention. Referring to FIG. 1, the PCB 10 has a three-layered structure. Specifically, the PCB 10 includes an outer grounding layer 11 (the lowermost layer of the PCB 10), a signal layer 15 (the uppermost layer of the PCB 10), and a power layer 13 located between the outer grounding layer 11 and the signal layer 15. Insulating materials 12 and 14 are respectively provided between the outer grounding layer 11 and the power layer 13, and between the power layer 13 and the signal layer 15. The description of the signal layer 15 as the uppermost layer and the description of the outer grounding layer 11 as the lowermost layer are provided for convenience of explanation, and denote the outermost layers of the PCB 10. However, it is understood that the locations of the signal layer 15 and the outer grounding layer 11 can be reversed.

The outer grounding layer 11 is a conductive metal layer to ground electronic parts and wire circuits and is located on a lowermost surface of the PCB 10. As opposed to the grounding layer of the conventional multi-layered PCB that is located within the PCB, the outer grounding layer 11 according to an aspect of the present invention is located an outer surface of the PCB 11. The outer grounding layer 11 may be provided on the front lowermost surface of the PCB 10 although aspects of the present invention are not limited thereto, and the outer grounding layer 11 can be, for example, formed in a strip shape.

The power layer 13 supplies power to the electronic parts, and can be provided in a plurality of regions having different voltage levels in order to apply power to the electronic parts according to the voltage level of each of the electronic parts. Also, the power layer 13 can include a region for supplying power to electronic parts that switch at a relatively high speed and another region for supplying power to electronic parts that switch at a relatively low speed.

The signal layer 15 is a pathway for electrical signals inputted to and outputted from the electronic parts, and includes a predetermined wire circuit that connects the electronic parts.

The insulating material 12 and 14 can be formed of a dielectric material having high insulating properties, and can include vias (not shown) that electrically connect the outer grounding layer 11, the power layer 13, and the signal layer 15.

FIG. 2 is a schematic cross-sectional view illustrating the shielding against electromagnetic interference (EMI) of the PCB 10 of FIG. 1, according to the example embodiment of the present invention. Referring to FIG. 2, electromagnetic waves radiate upwards from the PCB 10 on which the signal layer 15 is provided. However, electromagnetic waves that radiate downwards from the PCB 10 on which the outer grounding layer 11 is provided, are shielded because the outer grounding layer 11 is provided on the entire lower surface of the PCB 10 using a highly conductive material. Accordingly, since the radiation of the electromagnetic waves in the lower direction of the PCB 10 is blocked, the effect of the electromagnetic waves can be minimized by locating modules M that are sensitive to the electromagnetic waves in the lower side of the PCB 10 when arranging the electronic parts. For example, when the PCB 10 for driving or signal processing is provided on a rear surface of a module M such as a liquid crystal panel, the outer grounding layer 11 can be arranged to face the module M and the signal layer 15 on which electronic parts D are mounted can be arranged to face outwards away from the module M.

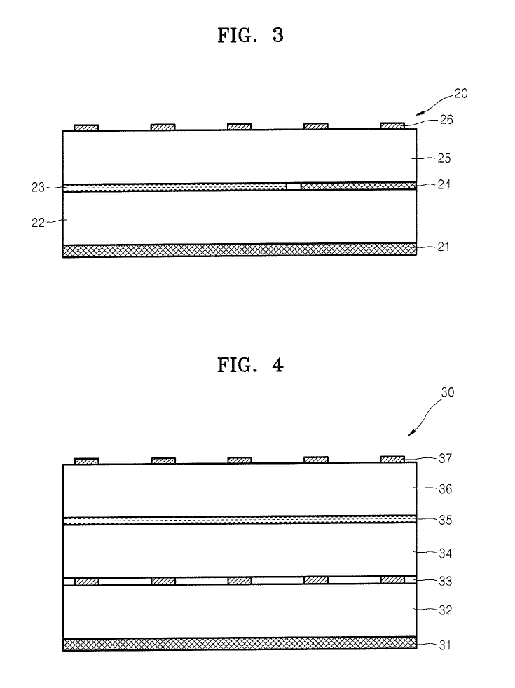

FIG. 3 is a schematic cross-sectional view illustrating a PCB 20 according to another example embodiment of the present invention. Referring to FIG. 3, the PCB 20 includes an outer grounding layer 21 (the lowermost layer of the PCB 20), a signal layer 26 (the uppermost layer of the PCB 20), and a power layer 23 and an intermediate grounding layer 24 located between the outer grounding layer 21 and the signal layer 26. The description of the signal layer 26 as the uppermost layer and the description of the outer grounding layer 21 as the lowermost layer are provided for convenience of explanation, and denote the outermost layers of the PCB 10. However, it is understood that the locations of the signal layer 26 and the outer grounding layer 21 can be reversed. Insulating materials 22 and 25 are respectively provided between the outer grounding layer 21 and the power layer 23 and the intermediate layer 24, and between the power layer 23 and the intermediate grounding layer 24 and the signal layer 26. The PCB 20 according to the present example embodiment is substantially the same as the PCB 10 described with reference to FIG. 1, with the exception of the power layer 23 and the intermediate grounding layer 24.

The power layer 23 supplies power to electronic parts. The power layer 23 can be divided into regions having different voltage levels in order to apply power to electronic parts having different voltage levels from each other.

The intermediate grounding layer 24 is connected to electronic parts that switch at a high speed (such as a central process unit (CPU)), and the outer grounding layer 21 is connected to electronic parts that switch at a relatively slow speed. Accordingly, since the grounding layer is divided into the intermediate grounding layer 24 and the outer grounding layer 21 based on the speed of signals that are to be processed, the generation of electromagnetic waves when particularly high speed signals are processed can be effectively repressed.

FIG. 4 is a schematic cross-sectional view illustrating a PCB 30 according to yet another example embodiment of the present invention. Referring to FIG. 4, the PCB 30 has a four-layered structure in which an outer grounding layer 31, a second signal layer 33, a power layer 35, and a first signal layer 37 are sequentially provided, and insulating materials 32, 34, and 36 are interposed between the layers. Vias (not shown) can be formed in each of the insulating materials 32, 34, and 36 to electrically connect, respectively, between the outer grounding layer 31 and the second signal layer 33, between the second signal layer 33 and the power layer 35, and between the power layer 35 and the first signal layer 37. In the PCB 30 according to the present example embodiment, circuits to electrically wire electronic parts are provided on the first and second signal layers 37 and 33. Electrical wires of the electronic parts are connected to either the first signal layer 37 or the second signal layer 33 according to the speed of the signal processing of the electronic parts, thereby effectively repressing the generation of electromagnetic waves from the PCB 30. For example, the radiation of electromagnetic waves due to high frequency clock signals can be reduced by connecting the electronic parts that switch at a lower speed to the first signal layer 37 located on the uppermost surface of the PCB 30. In contrast, electronic parts that switch at a higher speed are connected to the second signal layer 33 located between the outer grounding layer 31 and the power layer 35, so that electromagnetic waves generated from high speed clock signals can be absorbed by the outer grounding layer 31 and the power layer 35 Therefore, the radiation of high frequency noise generated from high frequency clock signals to the outside can be prevented.

As described above, the PCB 30 according to the present example embodiment, unlike the conventional four-layered PCB, includes the outer grounding layer 31 on the outermost surface of the PCB 30. Thus, the radiation of electromagnetic waves outward from the outer grounding layer 31 is prevented. Furthermore, the generation of electromagnetic waves from the PCB 30 can be effectively repressed by separating the signal layer to which the high speed switching electronic parts are connected from the signal layer to which the low speed switching electronic parts are connected.

Referring to FIG. 4, according to an aspect of the present invention, an intermediate grounding layer can be provided between the first signal layer 37 and the second signal layer 33 instead of the power layer 35. In this case, lines for supplying power to the electronic parts can be provided by the first signal layer 37 or the second signal layer 33. For example, to the low speed switching electronic parts, electrical signals can be transmitted through the first signal layer 37 and power can be supplied through lines (not shown) provided parallel to the first signal layer 37. To the high speed switching electronic parts, electrical signals can be transmitted through the second signal layer 33 and power can be supplied through lines (not shown) provided parallel to the second signal layer 33. In such a modification of the present example embodiment, a further effective repression of the generation of electromagnetic waves is possible by using layers on both sides of the second signal layer 33 as the grounding layers.

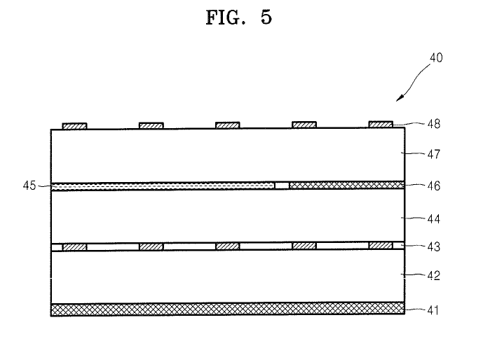

FIG. 5 is a schematic cross-sectional view illustrating a PCB 40 according to yet another example embodiment of the present invention. Referring to FIG. 5, the PCB 40 has a four-layered structure that includes an outer grounding layer 41 (the lowermost layer of the PCB 40), a second signal layer 43 located in a first intermediate layer on the lowermost layer of the PCB 40, a power layer 45 and an intermediate grounding layer 46 on different regions in a second intermediate layer of the PCB 40, and a first signal layer 48 (the uppermost layer of the PCB 40). Insulating materials 42, 44, and 47 are interposed, respectively, between the outer grounding layer 41 and the second signal layer 43, between the second signal layer 43 and the intermediate grounding layer 46, and between the intermediate grounding layer 46 and the first signal layer 48.

The PCB 40 according to the present example embodiment is substantially the same as the PCB 30 described with reference to FIG. 4 except that the power layer 45 and the intermediate grounding layer 46 of the PCB 40 are provided together in the second intermediate layer between the first and second signal layers 48 and 43.

In the PCB 40, the grounding layers (i.e., the outer grounding layer 41 and the intermediate grounding layer 46) are respectively formed in the lowermost layer and in the second intermediate layer. That is, both grounding layers are formed to repress the radiation of electromagnetic waves generated from high frequency clock signals by separately grounding electronic parts that have different switching speeds.

Hence, the high speed switching electronic parts are connected to the second signal layer 43 located in the first intermediate layer so that electromagnetic waves generated by the high frequency clock signals can be absorbed by the outer grounding layer 41, the power layer 45, and the intermediate grounding layer 46. Also, the high speed switching electronic parts may be connected to the intermediate grounding layer 46 so that high frequency noise generated from the high speed clock signals cannot be radiated to the outside.

However, even if the low speed switching electronic parts are connected to the outer grounding layer 41 or the first signal layer 48, which are the outermost layers of the PCB 40, the radiation of electromagnetic waves caused by the low speed switching electronic parts is insignificant because the low speed clock signals generate little high frequency noise.

As described above, in the PCB 40 according to the present example embodiment, the radiation of electromagnetic waves to the outside of the outer grounding layer 41 is repressed since the outer grounding layer 41 is provided on the outermost surface of the PCB 40. Furthermore, the generation of electromagnetic waves due to high speed clock signals can be effectively prevented using the second signal layer 43 and the intermediate grounding layer 46.

Although the example embodiments of the present invention have been described with respect to PCBs having a three-layered or a four-layered structure, aspects of the present invention are not limited thereto. That is, aspects of the present invention can also be applied to PCBs having a five-layered structure or more.

As described above, a PCB according to aspects of the present invention includes a grounding layer on an outermost surface of the PCB. Thus, the radiation of electromagnetic waves in a direction in which the grounding layer is provided is prevented. Furthermore, the generation of the electromagnetic waves can be effectively prevented by separately providing at least a signal layer and a grounding layer so that electronic parts that process signals can be separately connected according to the switching speed of signals.

While there have been illustrated and described what are considered to be example embodiments of the present invention, it will be understood by those skilled in the art and as technology develops that various changes and modifications may be made and equivalents may be substituted for elements thereof without departing from the true scope of the present invention. Many modifications, permutations, additions and sub-combinations may be made to adapt the teachings of the present invention to a particular situation without departing from the scope thereof. For example, in any of the provided example embodiments, the power layer may be omitted and power lines may be included to run in parallel with the signal layer or layers. Furthermore, three or more signal layers may be provided to connect to electrical wires of the electronic parts according to the speed of the signal processing of the electronic parts. Moreover, three or more grounding layers may be provided to connect to electronic parts according to the speed that the electronic parts switch. Accordingly, it is intended, therefore, that the present invention not be limited to the various example embodiments disclosed, but that the present invention includes all embodiments falling within the scope of the appended claims.

What is claimed is:

1. A printed circuit board having a multi-layered structure to connect to electronic parts and to shield against electromagnetic interference caused by radiation of electromagnetic waves, the printed circuit board comprising:
one or more signal layers to provide lines for electrical signals inputted to and outputted from the electronic parts; and
an outer grounding layer located on an outermost surface of the printed circuit board to block radiation of electromagnetic waves radiated from the lines of the one or more signal layers.

2. The printed circuit board as claimed in claim 1, wherein the one or more signal layers comprises a first signal layer located on another outermost surface opposite to the outermost surface where the outer grounding layer is located.

3. The printed circuit board as claimed in claim 2, further comprising:
a power layer between the first signal layer and the outer grounding layer to supply power to the electronic parts.

4. The printed circuit board as claimed in claim 2, wherein the one or more signal layers further comprises a second signal layer located between the outer grounding layer and the first signal layer.

5. The printed circuit board as claimed in claim 4, further comprising:
a power layer between the first signal layer and the second signal layer to supply power to the electronic parts.

6. The printed circuit board as claimed in claim 4, further comprising:
an intermediate grounding layer between the first signal layer and the second signal layer to block the radiation of the electromagnetic waves radiated from the lines of the one or more signal layers.

7. The printed circuit board as claimed in claim 6, further comprising:
a power layer between the first signal layer and the outer grounding layer to supply power to the electronic parts.

8. The printed circuit board as claimed in claim 6, wherein the one or more signal layers is further provided with power lines to supply power to the electronic parts.

9. The printed circuit board as claimed in claim 4, further comprising:
a power layer in a first region of a layer, between the first signal layer and the second signal layer, to supply power to the electronic parts; and
an intermediate grounding layer in a second region of the layer, between the first signal layer and the second signal layer, to block the radiation of the electromagnetic waves radiated from the lines of the one or more signal layers.

10. The printed circuit board as claimed in claim 6, wherein electronic parts having first speed clock signals are connected to the outer grounding layer, and electronic parts having second speed clock signals, higher than the first speed clock signals, are connected to the intermediate grounding layer.

11. The printed circuit board as claimed in claim 9, wherein electronic parts having first speed clock signals are connected to the outer grounding layer, and electronic parts having second speed clock signals, higher than the first speed clock signals, are connected to the intermediate grounding layer.

12. The printed circuit board as claimed in claim 4, wherein electronic parts having relatively first speed clock signals are connected to the first signal layer, and electronic parts having second speed clock signals, higher than the first speed clock signals, are connected to the second signal layer.

13. The printed circuit board as claimed in claim 1, further comprising:
insulating material to insulate the one or more signal layers and the outer grounding layer from each other.

14. The printed circuit board as claimed in claim 3, further comprising:
insulating material between the first signal layer and the power layer and between the power layer and the outer grounding layer to insulate the one or more signal layers, the power layer, and the outer grounding layer from each other.

15. The printed circuit board as claimed in claim 13, wherein the insulating material comprises vias to electrically connect the outer grounding layer and the one or more signal layers.

16. A method of shielding against electromagnetic interference from a printed circuit board caused by radiation of electromagnetic waves, the method comprising:
inputting and/or outputting electrical signals to/from electronic parts in one or more signal layers of the printed circuit board; and
blocking radiation of electromagnetic waves radiated from the one or more signal layers with an outer grounding layer located on an outermost surface of the printed circuit board.

17. The method as claimed in claim 16, wherein the inputting and/or the outputting of the electrical signals comprises: inputting and/or outputting the electrical signals to/from the electronic parts in a first signal layer located on another outermost surface opposite to the outermost surface of the printed circuit board.

18. The method as claimed in claim 17, further comprising:
supplying power to the electronic parts through a power layer located between the first signal layer and the outer grounding layer.

19. The method as claimed in claim 17, wherein the inputting and/or the outputting of the electrical signals further comprises:
inputting and/or outputting the electrical signals to/from the electronic parts in a second signal layer located between the outer grounding layer and the first signal layer.

20. The method as claimed in claim 19, further comprising:
blocking radiation of electromagnetic waves radiated from the one or more signal layers with an intermediate grounding layer located between the first signal layer and the second signal layer.

21. The method as claimed in claim 20, further comprising:
connecting electronic parts having first speed clock signals to the outer grounding layer; and
connecting electronic parts having second speed clock signals, higher than the first speed clock signals, to the intermediate grounding layer.

22. The method as claimed in claim 19, further comprising:
connecting electronic parts having first speed clock signals to the first signal layer; and
connecting electronic parts having second speed clock signals, higher than the first speed clock signals, to the second signal layer.

23. A printed circuit board having a multi-layered structure to connect to electronic parts and to shield against electromagnetic interference caused by radiation of electromagnetic waves, the printed circuit board comprising:
one or more signal layers to provide lines for electrical signals inputted to and outputted from the electronic parts;
an intermediate grounding layer located within the printed circuit board to block radiation of electromagnetic waves radiated from the lines of the one or more signal layers; and
an outer grounding layer located on an outermost surface of the printed circuit board to block the radiation of the electromagnetic waves radiated from the lines of the one or more signal layers.

24. The printed circuit board as claimed in claim 23, wherein the one or more signal layers comprises: a first signal layer located on another outermost surface opposite to the outermost surface where the outer grounding layer is located.

25. The printed circuit board as claimed in claim 24, further comprising:
a power layer between the first signal layer and the outer grounding layer to supply power to the electronic parts.

26. The printed circuit board as claimed in claim 24, wherein the one or more signal layers further comprises a second signal layer located between the outer grounding layer and the first signal layer.

27. The printed circuit board as claimed in claim 26, wherein the intermediate grounding layer is located between the first signal layer and the second signal layer.

28. The printed circuit board as claimed in claim 27, wherein the one or more signal layers is further provided with power lines to supply power to the electronic parts.

29. The printed circuit board as claimed in claim 26, further comprising:
a power layer in a first region of a layer, between the first signal layer and the second signal layer, to supply power to the electronic parts,
wherein the intermediate grounding layer is located in a second region of the layer.

30. The printed circuit board as claimed in claim 23, wherein electronic parts having first speed clock signals are connected to the outer grounding layer, and electronic parts having second speed clock signals, higher than the first speed clock signals, are connected to the intermediate grounding layer.

31. The printed circuit board as claimed in claim 26, wherein electronic parts having relatively first speed clock signals are connected to the first signal layer, and electronic parts having second speed clock signals, higher than the first speed clock signals, are connected to the second signal layer.
